(19) United States
(12) Patent Application Publication
(10) Pub. No.: US 2015/0082884 A1
(43) Pub. Date: Mar. 26, 2015

(54) PIEZOELECTRIC ACTUATOR MODULE, METHOD OF MANUFACTURING THE SAME, AND MEMS SENSOR HAVING THE SAME

(71) Applicant: SAMSUNG ELECTRO-MECHANICS CO., LTD., Suwon-Si (KR)

(72) Inventors: Seung Mo LIM, Suwon-Si (KR); Yun Sung KANG, Suwon-Si (KR); In Young KANG, Suwon-Si (KR); Jeong Suong YANG, Suwon-Si (KR); Hwa Sun LEE, Suwon-Si (KR)

(73) Assignee: SAMSUNG ELECTRO-MECHANICS CO., LTD., Suwon-Si (KR)

(21) Appl. No.: 14/320,625

(22) Filed: Jun. 30, 2014

(30) Foreign Application Priority Data
Sep. 25, 2013 (KR) 10-2013-0113979

(51) Int. Cl. H01L 41/09; G01P 3/02; H01L 41/27; H01L 41/083

(52) U.S. Cl. CPC H01L 41/09; H01L 41/083; G01P 3/02; H01L 41/27
USPC 73/504.12; 310/332; 29/25.35

(57) ABSTRACT

An actuator includes a multi-layer part having a multilayered piezoelectric part comprising a plurality of piezoelectric bodies and an electrode part connected to the multilayered piezoelectric part, and a support part displaceably supporting the multi-layer part. The multilayered piezoelectric part is polled in the same direction. One of the piezoelectric bodies expands or contracts in an opposite direction to another piezoelectric body.

### CROSS REFERENCE TO RELATED APPLICATION

This application claims the benefit of Korean Patent Application No. 10-2013-0113979, filed on Sep. 25, 2013, entitled “Piezoelectric Actuator Module, Method Of Manufacturing The Same, And MEMS Sensor Having The Same”, which is hereby incorporated by reference in its entirety into this application.

### BACKGROUND

1. Technical Field

Embodiments of the present invention generally relate to a piezoelectric actuator module, a method of manufacturing the same, and a micro electro mechanical systems (MEMS) sensor having the same.

2. Description of the Related Art

Unless otherwise indicated herein, the materials described in this section are not prior art to the claims herein and are not admitted to be prior art by inclusion in this section.

MEMS is a technology of manufacturing an ultra micro mechanical structure, such as a very large scale integrated circuit, an inertial sensor, a pressure sensor, and an oscillator, by processing silicon, crystal, glass, or the like. The MEMS component needs precision of a micrometer ( 1/1,000,000 meter) or less and may be mass-produced as a micro product at a low cost by applying a semiconductor micro process technology of repeating processes, such as a deposition process and an etching process.

Among the MEMS components, the piezoelectric actuator applies an electric field to a piezoelectric body to be contracted and expanded. Generally, a diaphragm coupled with the piezoelectric body may be deformed by the contraction and expansion of the piezoelectric body.

In order to improve displacement or to increase a vibration force, the piezoelectric actuator may be implemented as a multilayered piezoelectric actuator in which a plurality of piezoelectric bodies are stacked.

### PATENT DOCUMENT

(Patent Document 1) U.S. Pat. No. 6,232,701

### SUMMARY

Some embodiments of the present invention may provide a multilayered piezoelectric actuator module, a method of manufacturing a piezoelectric actuator module, and an MEMS sensor having the piezoelectric actuator module. The multilayered piezoelectric actuator module may include a multilayered piezoelectric part polled in the same direction and comprise one piezoelectric body and another piezoelectric body, both being adjacent to each other in the multilayered piezoelectric body, to be expanded and contracted to be opposite to each other. These piezoelectric bodies may serve as a variable diaphragm for each other, for example, but not limited to, to obtain large displacement and improve driving performance.

According to a preferred embodiment of the present invention, there is provided a piezoelectric actuator module, including: a multi-layer part including a multilayered piezoelectric part having a plurality of piezoelectric bodies and an electrode part connected to the multilayered piezoelectric part; and a support part displaceably supporting the multi-layer part. The multilayered piezoelectric part may be polled in the same direction, and one of the piezoelectric bodies may be expanded or contracted in an opposite direction to the other piezoelectric body.

The multilayered piezoelectric part of the multi-layer part may include a first piezoelectric body, and a second piezoelectric body expanding or contracting in an opposite direction to the first piezoelectric body. The first piezoelectric body may be stacked on the second piezoelectric body. The electrode part may be connected to the first piezoelectric body and the second piezoelectric body.

The electrode part of the multi-layer part may include a first electrode connected to the first piezoelectric body, a second electrode connected to the second piezoelectric body, and a third electrode disposed between the first piezoelectric body and the second piezoelectric body.

With respect to a stack direction of the multi-layer part, the second electrode may be disposed at a lower end of the multi-layer part with a portion contacting the support part. The second piezoelectric body may be disposed on an upper portion of the second electrode. The third electrode may be disposed between the second piezoelectric body and the first piezoelectric body. The first piezoelectric body may be disposed on an upper portion of the third electrode. The first electrode may be disposed on an upper portion of the first piezoelectric body.

A portion of the second electrode which does not contact the support part may be exposed to the outside of the piezoelectric actuator module.

An end of the first electrode may be connected to an end of the second electrode.

A predetermined first voltage may be applied to the first and second electrodes, and a predetermined second voltage may be applied to the third electrode. The first voltage may be different from the second voltage.

An electrode in which the first electrode and the second electrode are connected to each other may be a ground electrode.

The multilayered piezoelectric part of the multi-layer part may include an upper piezoelectric part and a lower piezoelectric part. The upper piezoelectric part may include a first upper piezoelectric body and a second upper piezoelectric body. The first upper piezoelectric body may be stacked on the second upper piezoelectric body. The lower piezoelectric part may include a first lower piezoelectric body and a second lower piezoelectric body. The first lower piezoelectric body may be stacked on the second lower piezoelectric body.

The electrode part connected to the multilayered piezoelectric part may include a first electrode, a second electrode, a third electrode, a fourth electrode, and a fifth electrode. With respect to the stack direction in which the multi-layer part is coupled with the support part, the first electrode may be disposed on an upper portion of the first upper piezoelectric body, the second electrode may be disposed between the first upper piezoelectric body and the second upper piezoelectric body, the third electrode may be disposed between the second upper piezoelectric body and the first lower piezoelectric body, the fourth electrode may be disposed between the first lower piezoelectric body and the second lower piezoelectric body, and the fifth electrode may be disposed on a lower portion of the second lower piezoelectric body.

The second electrode and the fourth electrode may be used as a ground electrode.

According to another preferred embodiment of the present invention, there is provided a method of manufacturing the piezoelectric actuator module as described above, including forming a wafer to be formed as a support part supporting the multi-layer part, depositing a lower electrode on one surface of the wafer, depositing a second piezoelectric body on one surface of the lower electrode and depositing an intermediate electrode on one surface of the second piezoelectric body, patterning the intermediate electrode deposited on the second piezoelectric body to have a predetermined pattern, depositing a first piezoelectric body on one surface of the second piezoelectric body and the intermediate electrode, and depositing an upper electrode on one surface of the first piezoelectric body.

The method of manufacturing a piezoelectric actuator module may further include patterning the upper electrode and forming a via hole to expose the lower electrode.

The method of manufacturing a piezoelectric actuator module may further include patterning a photoresist for depositing input and output electrodes on the upper electrode and the first piezoelectric body.

The method of manufacturing a piezoelectric actuator module may further include depositing the input and output electrode by the photoresist for depositing an input and output electrode and removing the photoresist for depositing the input and output electrode.

The method of manufacturing a piezoelectric actuator module may further include performing wire bonding to connect a wire for applying an external voltage to the piezoelectric actuator to the input and output electrode.

According to another preferred embodiment of the present invention, there is provided an angular velocity sensor, including a flexible substrate including a vibration member and a sensing member, a mass body connected to the flexible substrate, and a post supporting the flexible substrate. The vibration member may include a multi-layer part which includes a multilayered piezoelectric part comprising a plurality of piezoelectric bodies and an electrode part connected to the multilayered piezoelectric part. The multi-layer part may be displaceably supported on the post. The multilayered piezoelectric part may be polled in the same direction throughout such that one of the piezoelectric bodies may be expanded or contracted in an opposite direction to the other piezoelectric body.

The multilayered piezoelectric part of the multi-layer part may include a first piezoelectric body and a second piezoelectric body. The first piezoelectric body may be stacked on the second piezoelectric body. The second piezoelectric body may be expanded or contracted in an opposite direction to the first piezoelectric body.

The electrode part may be connected to a first piezoelectric body and a second piezoelectric body. The electrode part of the multi-layer part may include a first electrode connected to the first piezoelectric body, a second electrode connected to the second piezoelectric body, and a third electrode disposed between the first piezoelectric body and the second piezoelectric body.

A portion of the second electrode which does not contact a post may be exposed to the outside of the angular velocity sensor.

An end of the first electrode may be connected to an end of the second electrode. A predetermined first voltage may be applied to the first and second electrodes, and a predetermined second voltage may be applied to the third electrode. The first voltage may be different from the second voltage.

In some embodiments, a piezoelectric actuator may comprise multi-layer piezoelectric bodies, one or more electrode parts connected to the multilayer piezoelectric bodies, and a support part coupled to the multi-layer piezoelectric bodies. One of the multilayer piezoelectric bodies may expand or contract in an opposite direction to another of the multilayer piezoelectric bodies.

The one of the multilayer piezoelectric bodies may be disposed on the another of the multilayer piezoelectric bodies.

The multi-layer piezoelectric bodies may further comprise at least one of the multi-layer piezoelectric bodies expanding or contracting in the same direction as the one of the multilayer piezoelectric bodies, and at least one of the multi-layer piezoelectric bodies expanding or contracting in the same direction as the another of the multilayer piezoelectric bodies.

The electrode parts may be disposed between the multi-layer piezoelectric bodies or at the uppermost or lowermost ends of the multi-layer piezoelectric bodies.

The multi-layer piezoelectric bodies may be configured to be polled in the same direction.

### BRIEF DESCRIPTION OF THE DRAWINGS

Embodiments of the present invention will be more clearly understood from the following detailed description taken in conjunction with the accompanying drawings, in which:

FIGS. 1A and 1B are diagrams schematically illustrating exemplary embodiments of a piezoelectric actuator, in which FIG. 1A is a diagrammatic view of the piezoelectric actuator module according to one embodiment of the present invention, and FIG. 1B is a diagrammatic view of a piezoelectric actuator module according to another embodiment;

FIG. 2 is a schematic illustration of a piezoelectric actuator module according to a first preferred embodiment of the present invention;

FIGS. 3A and 3B are diagrammatic views schematically illustrating driving of the piezoelectric actuator module illustrated in FIG. 2;

FIGS. 4A to 4K are cross-sectional views schematically illustrating a method of manufacturing a piezoelectric actuator module illustrated in FIG. 2 according to the preferred embodiment of the present invention;

FIG. 5 is a schematic illustration of a piezoelectric actuator module according to a second preferred embodiment of the present invention;

FIGS. 6A and 6B are diagrammatic views schematically illustrating driving of the piezoelectric actuator module illustrated in FIG. 5; and

FIG. 7 is a cross-sectional view schematically illustrating an angular velocity sensor including the piezoelectric actuator module according to the preferred embodiment of the present invention.

### DESCRIPTION OF THE PREFERRED EMBODIMENTS

Embodiments of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. As used in this description and the appended claims, the singular forms “a”, “an” and “the” are intended to include the plural forms as well, unless the context clearly indicates otherwise. Further, in the description of embodiments of the present invention, when the detailed description of the related art would obscure the gist of the present invention, the description thereof is omitted.

Hereinafter, preferred embodiments of the present invention will be described in detail with reference to the attached drawings.

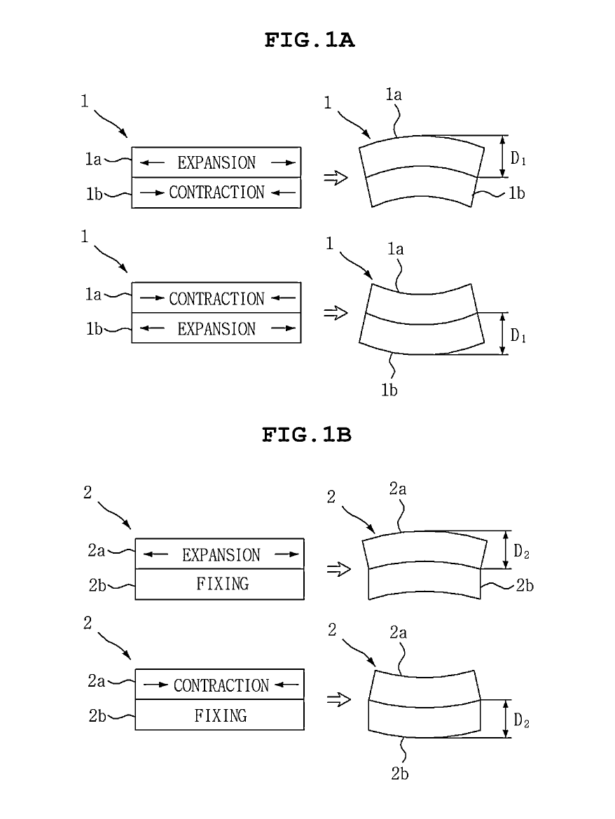

FIGS. 1A and 1B are diagrams schematically illustrating exemplary embodiments of a piezoelectric actuator according to a preferred embodiment of the present invention. FIG. 1A is a configuration diagram and a usage diagram of one embodiment of the present invention, and FIG. 1B is a configuration diagram and a usage diagram of another embodiment of the present application.

In the embodiment illustrated in FIG. 1B, A piezoelectric actuator 2 may include a piezoelectric body 2a and a diaphragm 2b. The piezoelectric body 2a may be fixedly coupled with the diaphragm 2b. When the piezoelectric body 2a is expanded by having a voltage applied, the diaphragm 2b supports the piezoelectric body 2a by a protruding displacement as illustrated by D₂ in FIG. 1B, and when the piezoelectric body 2a is contracted, the diaphragm 2b interacts with the contraction of the piezoelectric body 2a such that the protruding displacement occurs as illustrated by D₂ in FIG. 1B.

However, as illustrated in FIG. 1A, a piezoelectric actuator 1 according to the one embodiment of the present invention may include a first piezoelectric body 1a and a second piezoelectric body 1b without the diaphragm 2b shown in FIG. 1B.

The first piezoelectric body 1a and the second piezoelectric body 1b are polled in the same direction. When being applied with a voltage, the first piezoelectric body 1a and the second piezoelectric body 1b may be expanded and contracted in a direction opposite to each other. For example, when the first piezoelectric body 1a is expanded, the second piezoelectric body 1b is contracted, and when the first piezoelectric body 1a is contracted, the second piezoelectric body 1b is expanded.

Therefore, the first piezoelectric body 1a and the second piezoelectric body 1b may serve as a vibration support plate for each other and serve as an active diaphragm which varies in an opposite direction.

When the first piezoelectric body 1a is expanded, contraction of the second piezoelectric body 1b may make the first piezoelectric body 1a more expand, such that a protruding displacement occurs as illustrated by D₁ in FIG. 1A. When the second piezoelectric body 1b is expanded, contraction of the first piezoelectric body 1a makes the second piezoelectric body 1b further expand, such that a protruding displacement occurs as illustrated by D₁ in FIG. 1A.

Consequently, in the piezoelectric actuator according to the one embodiment of the present invention, a plurality of piezoelectric bodies may serve as vibration support plates to each other. Each of the plurality of piezoelectric bodies may serve as the active diaphragm which varies in an opposite direction to the other piezoelectric body, such that the displacement (confirmed by comparison of D₁ and D₂) may occur largely over the driving by the simple support plate, thereby improving the vibration force.

Hereinafter, the piezoelectric actuator module according to embodiments of the present invention will be described in detail.

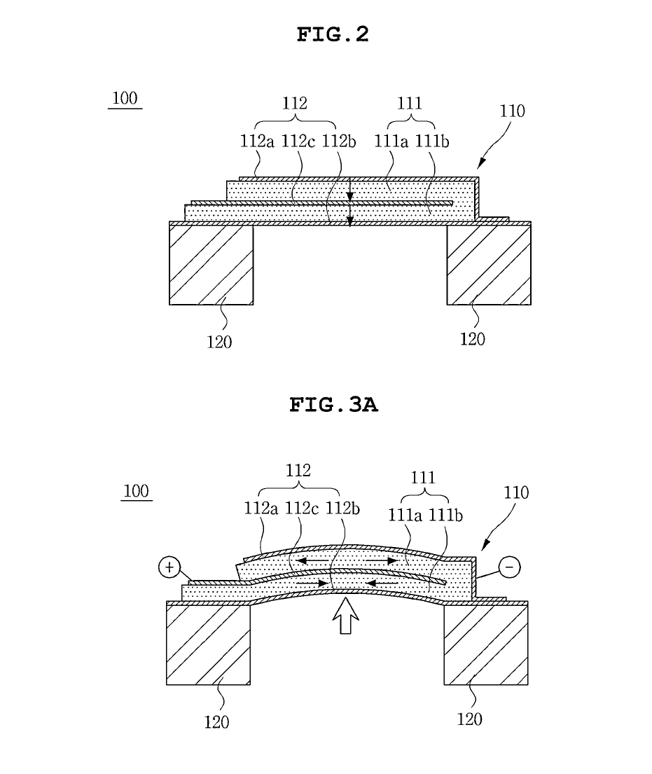

FIG. 2 is a configuration diagram schematically illustrating a piezoelectric actuator module according to a first preferred embodiment of the present invention. As illustrated in FIG. 2, the piezoelectric actuator module 100 may include a multi-layer part 110 and a support part 120.

When an electric field is applied to the multi-layer part 110 from the outside of the piezoelectric actuator module 100, the multi-layer part 110 contracts and expands to generate a vibration force. The multi-layer part 110 may include a multilayered piezoelectric part 111 and an electrode part 112. The support part 120 may support the multi-layer part 110 to facilitate displacement.

The multilayered piezoelectric part 111 is polled in the same direction. One of the piezoelectric bodies of the multilayered piezoelectric part 111 contacting each other is expanded or contracted in an opposite direction to the other piezoelectric body of the multilayered piezoelectric part 111.

For example, the multilayered piezoelectric part 111 may include a first piezoelectric body 111a and a second piezoelectric body 111b. The first piezoelectric body 111a may be stacked on the second piezoelectric body 111b.

The first piezoelectric body 111a and the second piezoelectric body 111b are polled in the same direction as illustrated in FIG. 2, and are expanded or contracted in an opposite direction to each other.

The first piezoelectric body 111a and the second piezoelectric body 111b are not coupled with a support plate, but the ends of the first piezoelectric body 111a and the second piezoelectric body 111b are supported to the support part 120. Accordingly, the first piezoelectric body 111a and the second piezoelectric body 111b can be expanded or contracted in an opposite direction to each other without having a separate support plate or diaphragm.

The first piezoelectric body 111a and the second piezoelectric body 111b may serve as the vibration support plate for each other and serve as the active diaphragm which varies in an opposite direction.

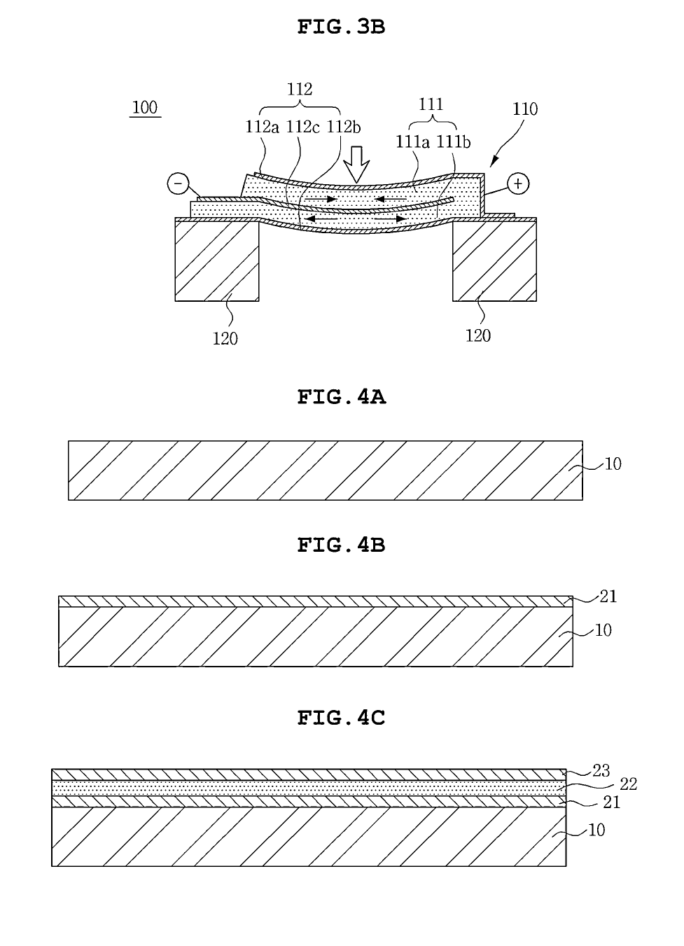

Exemplary embodiments will be described in FIGS. 3A and 3B.

The electrode part 112 may include a first electrode 112a, a second electrode 112b, and a third electrode 112c which are connected to the multilayered piezoelectric part 111.

For instance, the first electrode 112a is connected to the first piezoelectric body 111a, the second electrode 112b is connected to the second piezoelectric body 111b, and the third electrode 112c is disposed between the first piezoelectric body 111a and the second piezoelectric body 111b.

The first electrode 112a and the second electrode 112b which are connected to each other may be used as a ground electrode.

With respect to a stack direction of the multi-layer part 110 coupled with the support part 120, the second electrode 112b may be disposed at a lower end of the multi-layer part 110 and a portion coupled with the support part 120, the second piezoelectric body 111b may be disposed on an upper portion of the second electrode 112b, the third electrode 112c may be disposed between the second piezoelectric body 111b and the first piezoelectric body 111a, the first piezoelectric body 111a may be disposed on an upper portion of the third electrode 112c, and the first electrode 112a may be disposed on an upper portion of the first piezoelectric body 111a.

In the multi-layer part 110, the first electrode 112a may be formed as an upper electrode, the second electrode 112b may be formed as a lower electrode, and the third electrode 112c may be formed as an intermediate electrode. The first electrode 112a may be disposed at the uppermost layer of the multi-layer part 110, and the second electrode 112b is disposed at the lowermost layer of the multi-layer part 110.

The support part 120 may be coupled with one or both ends of the multi-layer part 110 to support the multi-layer part 110 for displacement. Therefore, a portion of the second electrode 112b which does not contact the support part 120 may be exposed to the outside of the piezoelectric actuator module 100.

Hereinafter, a driving principle and an operation state of the piezoelectric actuator module according to the first preferred embodiment of the present invention illustrated in FIG. 2 will be described in more detail with reference to FIGS. 3A and 3B.

FIGS. 3A and 3B schematically illustrate the driving of the piezoelectric actuator module 100 illustrated in FIG. 2. As illustrated in FIG. 3A, an electric field is applied to the electrode connected to the first electrode 112a and the second electrode 112b of the multi-layer part 110 of the piezoelectric actuator module 100, which are connected to each other, and the third electrode 112c, respectively. For example, when as represented in FIG. 3A by + and −, a negative voltage is applied to the first electrode 112a and the second electrode 112b which are connected to each other and a positive voltage is applied to the third electrode 112c, the first piezoelectric body 111a is expanded and at the same time, the second piezoelectric body 111b is contracted as represented by an arrow.

Therefore, a central portion of the multi-layer part 110 is displaced upwardly as represented in FIG. 3A by an arrow, ends of the multi-layer part 110 being supported by the support parts 120.

Next, as illustrated in FIG. 3B, an electric field opposite to that of FIG. 3A is applied to the electrode in which the first electrode 111a and the second electrode 112b of the multi-layer part 110 of the piezoelectric actuator module 100 are connected to each other and the third electrode 112c, respectively. For instance, when a positive voltage is applied to the electrode in which the first electrode 112a and the second electrode 112b are connected to each other and a negative voltage is applied to the third electrode 112c, as represented in FIG. 3B by an arrow, the first piezoelectric body 111a is contracted and at the same time, the second piezoelectric body 111b is expanded.

Therefore, the central portion of the multi-layer part 110 is displaced downwardly as represented in FIG. 3B by an arrow, The ends of the multi-layer part 110 are supported by the support parts 120.

By the above configuration, the first piezoelectric body 111a and the second piezoelectric body 111b are contracted and expanded opposite to each other, such that a large displacement may occur, thereby which may improve the driving performance.

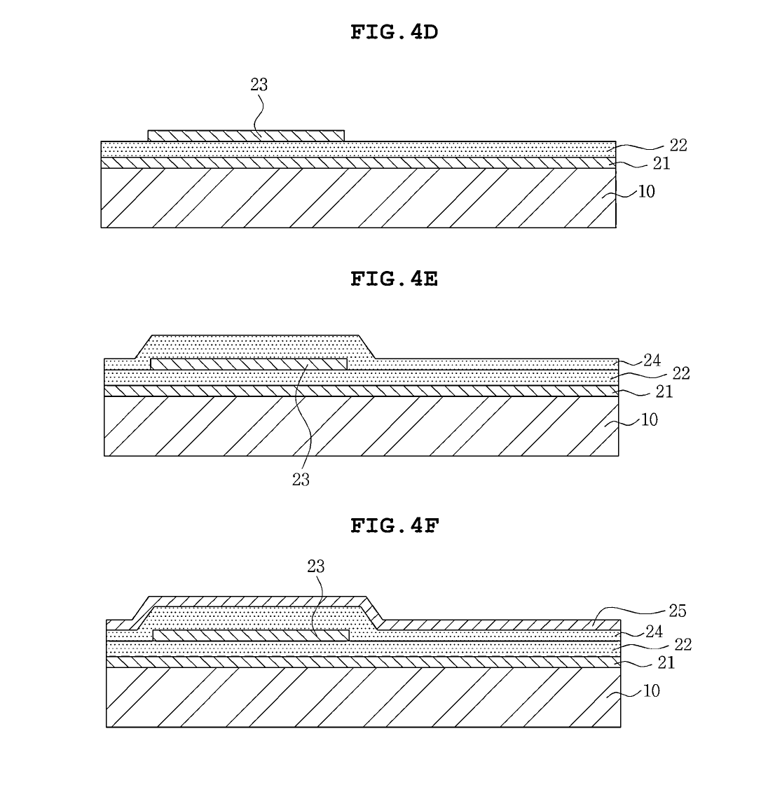

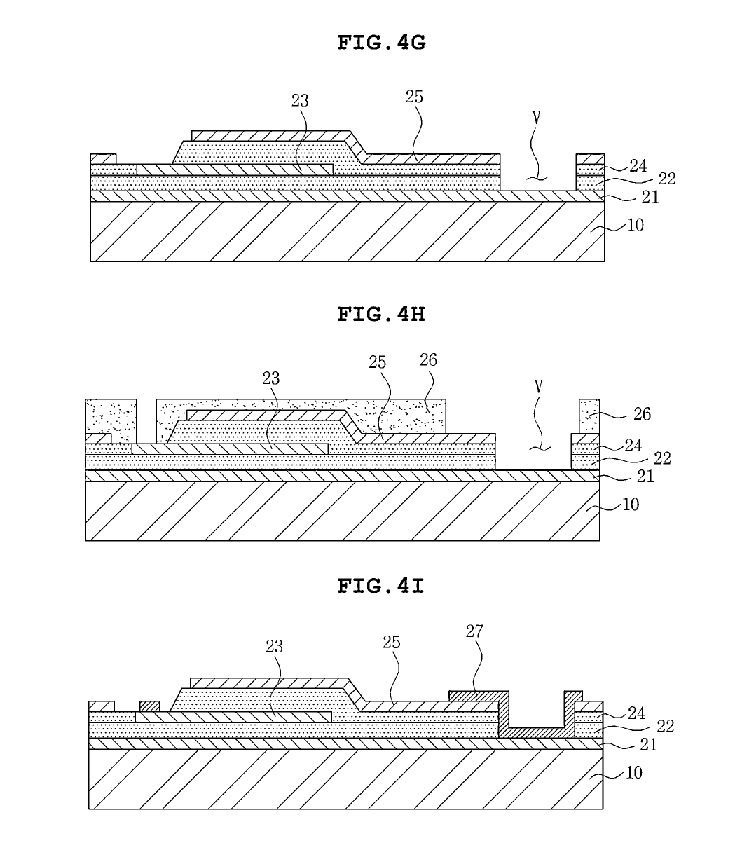

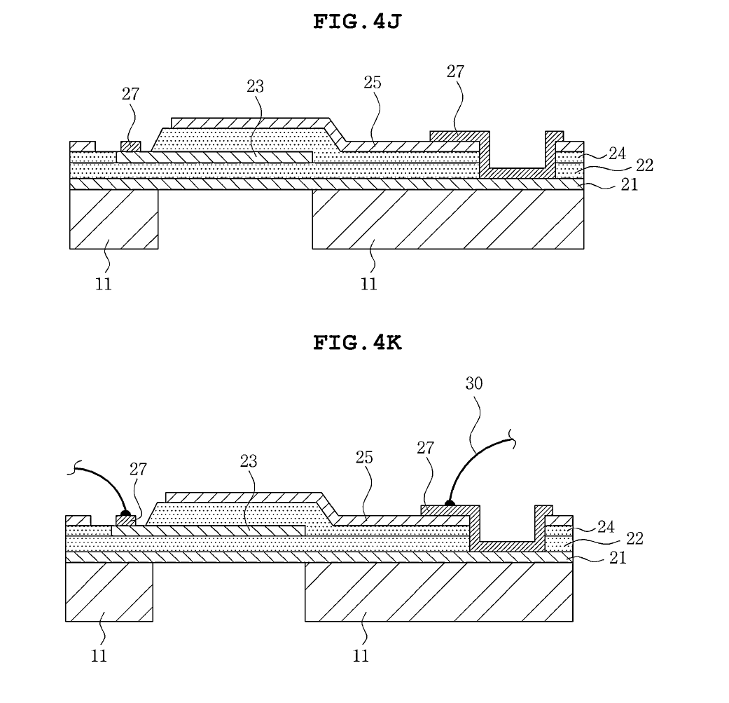

FIGS. 4A to 4K are cross-sectional views schematically illustrating a method for manufacturing a piezoelectric actuator module according to a preferred embodiment of the present invention to which he first preferred embodiment of a piezoelectric actuator module illustrated in FIG. 2 may be applied.

FIG. 4A illustrates an exemplary embodiment of forming a wafer. As illustrated in FIG. 4A, the wafer 10 is prepared. Further, an outer circumferential surface of the wafer 10 may be provided with an oxide layer (not illustrated).

Next, FIG. 4B illustrates an exemplary embodiment of depositing the lower electrode. For example, as illustrated in FIG. 4B, a lower electrode 21 is deposited on one surface of the wafer 10.

Next, FIG. 4C illustrates an exemplary embodiment of depositing the second piezoelectric body and the intermediate electrode. For instance, as illustrated in FIG. 4C, a second piezoelectric body 22 is deposited on one surface of the lower electrode 21 which is deposited on the wafer 10. An intermediate electrode 23 is deposited on one surface of the second piezoelectric body 22. With respect to the stack direction, the second piezoelectric body 22 is deposited on an upper portion of the lower electrode 21 which is deposited on the wafer 10, and the intermediate electrode 23 is deposited on the upper portion of the second piezoelectric body 22, or vice versa.

Next, FIG. 4D illustrates an exemplary embodiment of patterning the intermediate electrode. As illustrated in FIG. 4D, the intermediate electrode 23 may be deposited on the upper portion of the second piezoelectric body 22 and patterned to have a predetermined pattern shape.

Next, FIG. 4E illustrates an exemplary embodiment of depositing the first piezoelectric body. As illustrated in FIG. 4E, a first piezoelectric body 24 may be deposited on upper portions of the second piezoelectric body 22 and the intermediate electrode 23.

Next, FIG. 4F illustrates an exemplary embodiment of depositing an upper electrode. As illustrated in FIG. 4F, an upper electrode 25 is deposited on the upper portion of the first piezoelectric body 24.

Next, FIG. 4G illustrates an exemplary embodiment of patterning the upper electrode and forming a via hole. As illustrated in FIG. 4G, the upper electrode 25 illustrated in FIG. 4F is patterned to have a predetermined pattern shape, and a via V is formed by using, for example, but not limited to, a method for etching the upper electrode 25, the first piezoelectric body 24, and the second piezoelectric body 22, and the like to expose the lower electrode 21.

Next, FIG. 4H illustrates an exemplary embodiment of patterning a photoresist for depositing input and output electrodes. In FIG. 4H, a photoresist 26 for depositing input and output electrodes is patterned on the upper electrode 25 and the first piezoelectric body 24 illustrated in FIG. 3G.

Next, FIG. 4I illustrates an exemplary embodiment of depositing input and output electrodes and removing the photoresist. In FIG. 4I, the input and output electrodes 27 are deposited by the photoresist 26 for depositing input and output electrodes illustrated in FIG. 4H, and then the photoresist 26 for creating input and output electrodes is removed. The input and output electrodes 27 may be made of AU.

Next, FIG. 4J illustrates an exemplary embodiment of forming the support part. As illustrated in FIG. 4J, the support part 11 is formed by etching the wafer 10. A portion of the lower electrode 21 may be exposed to the outside of the piezoelectric actuator by the support part 11.

Next, FIG. 4K illustrates an exemplary embodiment of performing wire bonding. The step of performing of wire bonding is to electrically connect a piezoelectric actuator to an external device by coupling a wire 30 to the input and output electrodes 27.

A voltage is applied to the first piezoelectric body 24 and the second piezoelectric body 22 so as to be polled in the same direction, thereby obtaining the piezoelectric actuator module according to the preferred embodiment of the present invention.

As the piezoelectric actuator module is configured without including a separate diaphragm coupled with the lower electrode 21 or the upper electrode 25, when an electric field is applied through the wire 30 from the outside of the piezoelectric actuator module 100, the piezoelectric actuator module 100 can be displaced upwardly or downwardly as illustrated in FIGS. 3A and 3B.

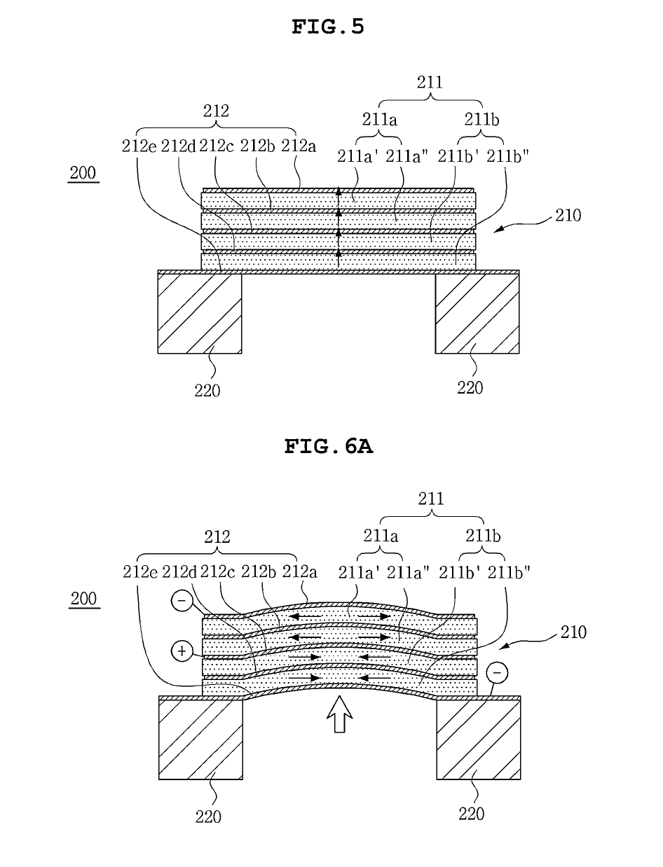

FIG. 5 is a configuration diagram schematically illustrating a piezoelectric actuator module according to a second preferred embodiment of the present invention. As illustrated in the first preferred embodiment shown in FIG. 2, the piezoelectric actuator module 100 has a two-layered piezoelectric part. However, in the second preferred embodiment shown in FIG. 5 a piezoelectric actuator module 200 has a four-layered piezoelectric part.

The piezoelectric actuator module 200 may include a multi-layer part 210 and a support part 220.

The multi-layer part 210 may include a multilayered piezoelectric part 211 and an electrode part 212. The support part 220 displaceably supports the multi-layer part 210.

The multilayered piezoelectric part 211 may include an upper piezoelectric part 211a and a lower piezoelectric part 211b, and be polled in the same direction so as to allow the upper piezoelectric part 211a and the lower piezoelectric part 211b to be expanded or contracted in an opposite direction to each other.

The upper piezoelectric part 211a may include a first upper piezoelectric body 211a′ and a second upper piezoelectric body 211a″. The first upper piezoelectric body 211a′ may be stacked on the second upper piezoelectric body 211a″.

The lower piezoelectric part 211b may include a first lower piezoelectric body 211b′ and a second lower piezoelectric body 211b″. The first lower piezoelectric body 211b′ may be stacked on the second lower piezoelectric body 211b″

The upper piezoelectric part 211a may be stacked on the lower piezoelectric part 211b, and the upper and lower piezoelectric parts 211a and 211b are polled in the same direction as represented by an arrow in FIG. 5.

The electrode parts 212 may be each connected to the multilayered piezoelectric parts 211 or may include a first electrode 212a, a second electrode 212b, a third electrode 212c, a fourth electrode 212d, and a fifth electrode 212e which are implemented as ground electrodes.

For example, with respect to a stack direction of the multi-layer part 210 which is coupled with the support part 220, the first electrode 212a is disposed on an upper portion of the first upper piezoelectric body 211a′, the second electrode 212b is disposed between the first upper piezoelectric body 211a′ and the second upper piezoelectric body 211a″, the third electrode 212c is disposed between the second upper piezoelectric body 211a″ and the first lower piezoelectric body 211b′, the fourth electrode 212d is disposed between the first lower piezoelectric body 211b′ and the second lower piezoelectric body 211b″, and the fifth electrode 212e is disposed on a lower portion of the second lower piezoelectric body 211b″, that is, a lower end of the multi-layer part 210.

The second electrode 212b and/or the fourth electrode 212d may be used as the ground electrode.

The support part 220 may be coupled with one or both ends of the multi-layer part 210 to displaceably support the multi-layer part 210. Therefore, a portion of the fifth electrode 212e which does not contact the support part is exposed to the outside of the piezoelectric actuator module 200.

In another embodiment of the multilayered piezoelectric part, the upper piezoelectric body may consist of a first upper piezoelectric body, a second upper piezoelectric body, and a third upper piezoelectric body, and the lower piezoelectric body may consist of a first lower piezoelectric body.

In another embodiment of the multilayered piezoelectric part, the upper piezoelectric body may consist of the first upper piezoelectric body and the lower piezoelectric body may consist of a first lower piezoelectric body, a second lower piezoelectric body, and a third lower piezoelectric body.

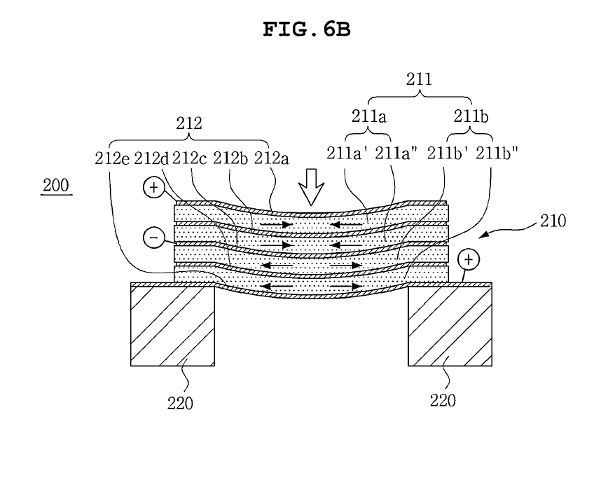

Hereinafter, the driving principle and the operation of the piezoelectric actuator module according to the second preferred embodiment of the present invention illustrated in FIG. 5 will be described in more detail with reference to FIGS. 6A and 6B.

FIGS. 6A and 6B are diagrams schematically illustrating the driving of the piezoelectric actuator module illustrated in FIG. 5.

As illustrated in FIG. 6A, in the piezoelectric actuator module 200, when an electric field is applied to the electrode parts 212 of the multi-layer part 210, respectively, the multilayered piezoelectric part 211 is expanded or contracted.

For example, as represented by + and −, when a negative voltage is applied to the first electrode 212a and the fifth electrode 212e, respectively, and a positive voltage is applied to the third electrode 212c, as represented by an arrow, the first upper piezoelectric body 211a′ and the second upper piezoelectric body 211a″ which are the upper piezoelectric body 211a are expanded, and at the same time, the first lower piezoelectric body 211b′ and the second lower piezoelectric body 211b″ which are the lower piezoelectric part 211b are contracted. Therefore, a central portion of the multi-layer part 210 is displaced upwardly as represented in FIG. 6A by an arrow in the state in which an end of the multi-layer part 210 is supported to the support part 220.

FIG. 6B shows an example when an electric field opposite to that illustrated in FIG. 6A is applied to the electrode parts 212 of the multi-layer part 210 of the piezoelectric actuator module 200. In FIG. 6B, when a positive voltage is applied to the first electrode 212a and the fifth electrode 212e, respectively, and a negative voltage is applied to the third electrode 212c, as represented by an arrow, the first upper piezoelectric body 211a′ and the second upper piezoelectric body 211a″ which are the upper piezoelectric body 211a are contracted, and the first lower piezoelectric body 211b′ and the second lower piezoelectric body 211b″ which are the lower piezoelectric part 211b are expanded. Therefore, the central portion of the multi-layer part 210 is displaced down as represented in FIG. 6B by an arrow in the state in which the end of the multi-layer part 210 is displaceably supported by the support part 220.

By the above configuration, the upper piezoelectric part 211a and the lower piezoelectric part 211b are contracted and expanded opposite of each other to cause a large overall displacement. The upper piezoelectric part 211a and the lower piezoelectric part 211b are each configured of multilayers to obtain a larger force than in the occurrence of displacement with less layers.

In the piezoelectric actuator module 200 according to the second preferred embodiment of the present invention, the electrode parts may be variously implemented as another pattern to which the concept of the present invention is applied.

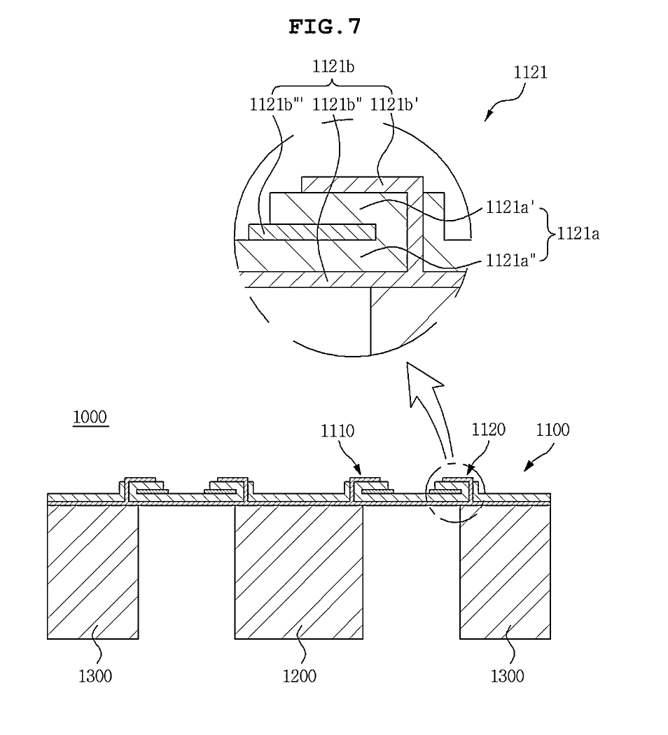

FIG. 7 is a cross-sectional view schematically illustrating an angular velocity sensor including a piezoelectric actuator module according to the preferred embodiment of the present invention. The angular velocity sensor 1000 may include a flexible substrate part 1100, a mass body 1200, and a post 1300.

The mass body 1200 may be displaced by an inertial force, a Coriolis force, an external force, a driving force, and the like. The mass body 1200 is coupled with the flexible substrate part 1100.

The flexible substrate part 1100 is provided with a sensing member 1110 and a vibration member 1120. As the flexible substrate part 1100 is coupled with the post 1300, the mass body 1200 is displaceably supported by the post 1300 by the flexible substrate part 1100.

The vibration member 1120 of the flexible substrate part 1100 may be configured as the piezoelectric actuator module 100 illustrated in FIG. 2. The vibration member 1120 may include a multi-layer part 1121.

The sensing member 1110 may be formed in, for example, a piezoelectric type, a piezoresistive type, a capacitive type, an optical scheme, and the like, but is not particularly limited thereto.

When an electric field is applied to the multi-layer part 1121, the multi-layer part 1121 is contracted and expanded to generate a vibration force. The multi-layer part 1121 may include a multilayered piezoelectric part 1121a and an electrode part 1121b. The post 1300 displaceably supports the multi-layer part 1121.

The multilayered piezoelectric part 1121a is polled in the same direction such that one of the piezoelectric bodies of the multilayered piezoelectric part 1121a contacting each other expands or contracts in opposite directions each other.

The multilayered piezoelectric part 1121a may include a first piezoelectric body 1121a′ and a second piezoelectric body 1121a″. The first piezoelectric body 1121a′ may be stacked on the second piezoelectric body 1121a″.

The first piezoelectric body 1121a′ and the second piezoelectric body 1121a″ may be polled in the same direction to expand or contract in opposite to each other.

The first piezoelectric body 1121a′ and the second piezoelectric body 1121a″ are not coupled with a separate support plate, but the ends of the first piezoelectric body 1121a′ and the second piezoelectric body 1121a″ are supported by the post 1300, and the first piezoelectric body 1121a′ and the second piezoelectric body 1121a″ are expanded or contracted in an opposite to each other.

The electrode part 1121b may include a first electrode 1121b′, a second electrode 1121b″, and a third electrode 1121b′″ which are each connected to the multilayered piezoelectric part 1121a.

For example, the first electrode 1121b′ is connected to the first piezoelectric body 1121a′, the second electrode 1121b″ is connected to the second piezoelectric body 1121a″, and the third electrode 1121b′″ is disposed between the first piezoelectric body 1121a′ and the second piezoelectric body 1121a″.

The first electrode 1121b′ and the second electrode 1121b″ may have ends connected to each other and may be used as a ground electrode.

With respect to the stack direction of the multi-layer part 1121 which is coupled with the post 1300, the second electrode 1121b″ may be disposed at a lower end of the multi-layer part 1121 and a portion contacting the post 1300, the second piezoelectric body 1121a″ may be disposed on an upper portion of the second electrode 1121b″, the third electrode 1121b′″ may be disposed between the second piezoelectric body 1121a″ and the first piezoelectric body 1121a′, the first piezoelectric body 1121a′ may be disposed on an upper portion of the third electrode 1121b′″, and the first electrode 1121b′ may be disposed on an upper portion of the first piezoelectric body 1121a′.

For example, in the multi-layer part 1121, the first electrode 1121b′ is formed as an upper electrode, the second electrode 1121b″ is formed as a lower electrode, and the third electrode 1121b′″ is formed as an intermediate electrode. The first electrode 1121b′ is disposed at the uppermost layer of the multi-layer part 1121, and the second electrode 1121b″ is disposed at the lowermost layer of the multi-layer part 1121.

The angular velocity sensor including the piezoelectric actuator module according to the preferred embodiment of the present invention may vibrate the vibration member 1120 to sense an angular velocity. The vibration member 120 may be vibrated at high efficiency by the piezoelectric part 1121a of a double layer, such that the angular velocity sensor may be implemented to more accurately perform the sensing.

According to the preferred embodiments of the present invention, it is possible to obtain the multilayered piezoelectric actuator module, the method of manufacturing a piezoelectric actuator module, and the MEMS sensor having the piezoelectric actuator module, in which as the multilayered piezoelectric actuator module includes the multilayered piezoelectric part polled in the same direction and have one piezoelectric body and the other piezoelectric body, which are adjacent to each other in the multilayered piezoelectric body, to expand and contract in opposite to each other. These piezoelectric bodies may serve as a variable diaphragm for each other, thereby obtaining a large displacement and improving the driving performance.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims. Additionally, the illustrative discussions above are not intended to be exhaustive or to limit the invention to the precise forms disclosed.

What is claimed is:

1. A piezoelectric actuator module, comprising:
a multi-layer part including a multilayered piezoelectric part comprising a plurality of piezoelectric bodies and an electrode part connected to the multilayered piezoelectric part; and
a support part displaceably supporting the multi-layer part,
wherein the multilayered piezoelectric part is polled in the same direction, and one of the piezoelectric bodies expands or contracts in an opposite direction to another piezoelectric body.

2. The piezoelectric actuator module as set forth in claim 1, wherein the multilayered piezoelectric part includes:
a first piezoelectric body; and
a second piezoelectric body expanding or contracting in an opposite direction to the first piezoelectric body,
wherein the first piezoelectric body is stacked on the second piezoelectric body, and
wherein the electrode part is connected to the first piezoelectric body and the second piezoelectric body.

3. The piezoelectric actuator module as set forth in claim 2, wherein the electrode part includes:
a first electrode connected to the first piezoelectric body;
a second electrode connected to the second piezoelectric body; and
a third electrode disposed between the first piezoelectric body and the second piezoelectric body.

4. The piezoelectric actuator module as set forth in claim 3, wherein:
the second electrode is disposed at a lower end of the multi-layer part and a portion contacting the support part,
the second piezoelectric body is disposed on an upper portion of the second electrode,
the third electrode is disposed between the second piezoelectric body and the first piezoelectric body,
the first piezoelectric body is disposed on an upper portion of the third electrode, and
the first electrode is disposed on an upper portion of the first piezoelectric body.

5. The piezoelectric actuator module as set forth in claim 4, wherein a portion of the second electrode which does not contact the support part is exposed to the outside of the piezoelectric actuator module.

6. The piezoelectric actuator module as set forth in claim 4, wherein an end of the first electrode is connected to an end of the second electrode.

7. The piezoelectric actuator module as set forth in claim 4, wherein a first voltage is applied to the first and second electrodes, and a second voltage is applied to the third electrode, the first voltage being different from the second voltage.

8. The piezoelectric actuator module as set forth in claim 4, wherein an electrode in which the first electrode and the second electrode are connected to each other is a ground electrode.

9. The piezoelectric actuator module as set forth in claim 1, wherein the multilayered piezoelectric part comprise:
an upper piezoelectric part comprising a first upper piezoelectric body and a second upper piezoelectric body, wherein the first upper piezoelectric body is disposed on the second upper piezoelectric body; and
a lower piezoelectric part comprising a first lower piezoelectric body and a second lower piezoelectric body, wherein the first lower piezoelectric body is disposed on the second lower piezoelectric body.

10. The piezoelectric actuator module as set forth in claim 9, wherein:
the electrode part includes a first electrode, a second electrode, a third electrode, a fourth electrode, and a fifth electrode,
the first electrode is disposed on an upper portion of the first upper piezoelectric body,
the second electrode is disposed between the first upper piezoelectric body and the second upper piezoelectric body,
the third electrode is disposed between the second upper piezoelectric body and the first lower piezoelectric body,
the fourth electrode is disposed between the first lower piezoelectric body and the second lower piezoelectric body, and
the fifth electrode is disposed on a lower portion of the second lower piezoelectric body.

11. The piezoelectric actuator module as set forth in claim 10, wherein the second electrode and the fourth electrode are used as a ground electrode.

12. A method of manufacturing a piezoelectric actuator module, comprising:
forming a wafer to be formed as a support part for supporting multilayered piezoelectric bodies;
depositing a lower electrode on one surface of the wafer;
depositing a second piezoelectric body on one surface of the lower electrode;
depositing an intermediate electrode on one surface of the second piezoelectric body;
patterning the intermediate electrode to have a predetermined pattern;
depositing a first piezoelectric body on one surface of the second piezoelectric body and the intermediate electrode; and
depositing an upper electrode on one surface of the first piezoelectric body.

13. The method as set forth in claim 12, further comprising:
patterning the upper electrode and forming a via hole to expose the lower electrode.

14. The method as set forth in claim 13, further comprising:
patterning a photoresist for depositing input and output electrodes on the upper electrode and the first piezoelectric body.

15. The method as set forth in claim 14, further comprising:
depositing the input and output electrodes by the photoresist and removing the photoresist.

16. The method as set forth in claim 15, further comprising:
performing wire bonding to connect a wire for applying an external voltage to the piezoelectric actuator to the input and output electrodes.

17. An angular velocity sensor, comprising:
a flexible substrate including a vibration member and a sensing member;
a mass body connected to the flexible substrate; and
a post supporting the flexible substrate,
wherein the vibration member includes a multi-layer part which includes a multilayered piezoelectric part comprising a plurality of piezoelectric bodies and an electrode part connected to the multilayered piezoelectric part, the multi-layer part is displaceably supported to the post, the multilayered piezoelectric part is polled in the same direction, and one of the piezoelectric bodies expands or contracts in an opposite direction to another piezoelectric body.

18. The angular velocity sensor as set forth in claim 17, wherein the multilayered piezoelectric part includes a first piezoelectric body and a second piezoelectric body, the first piezoelectric body is stacked on the second piezoelectric body, and the second piezoelectric body expands or contracts in an opposite direction to the first piezoelectric body.

19. The angular velocity sensor as set forth in claim 17, wherein the electrode part is connected to a first piezoelectric body and a second piezoelectric body, and
the electrode part includes a first electrode connected to the first piezoelectric body, a second electrode connected to the second piezoelectric body, and a third electrode disposed between the first piezoelectric body and the second piezoelectric body.

20. The angular velocity sensor as set forth in claim 19, wherein a portion of the second electrode which does not contact the post is exposed to the outside of the angular velocity sensor.

21. The angular velocity sensor as set forth in claim 19, wherein an end of the first electrode is connected to an end of the second electrode, a first voltage is applied to the first and second electrodes, and a second voltage is applied to the third electrode, the first voltage different from the second voltage.

22. A piezoelectric actuator, comprising:
multi-layer piezoelectric bodies, one of the multilayer piezoelectric bodies expanding or contracting in an opposite direction to another of the multilayer piezoelectric bodies;
one or more electrode parts connected to the multilayer piezoelectric bodies; and
a support part coupled to the multi-layer piezoelectric bodies.

23. The piezoelectric actuator of claim 22, wherein the one of the multilayer piezoelectric bodies is disposed on the another of the multilayer piezoelectric bodies.

24. The piezoelectric actuator of claim 23, wherein the multi-layer piezoelectric bodies further comprises:
at least one of the multi-layer piezoelectric bodies expanding or contracting in the same direction as the one of the multilayer piezoelectric bodies; and
at least one of the multi-layer piezoelectric bodies expanding or contracting in the same direction as the another of the multilayer piezoelectric bodies.

25. The piezoelectric actuator of claim 23, wherein the electrode parts are disposed between the multi-layer piezoelectric bodies or at the uppermost or lowermost ends of the multi-layer piezoelectric bodies.

26. The piezoelectric actuator of claim 23, wherein the multi-layer piezoelectric bodies are configured to be polled in the same direction.
